(19) United States
(12) Patent Application Publication
(10) Pub. No.: US 2007/0017802 A1
(43) Pub. Date: Jan. 25, 2007

(54) Automatic in-line sputtering system with an integrated surface corona pretreatment

(75) Inventor: Geeng-Jen Sheu, Taichung City (TW)

Correspondence Address: BIRCH STEWART KOLASCH & BIRCH, PO BOX 747, FALLS CHURCH, VA, 22040-0747, US

(73) Assignee: HSIUPING INSTITUTE OF TECHNOLOGY

(21) Appl. No.: 11/476,659

(22) Filed: Jun. 29, 2006

(30) Foreign Application Priority Data
Jul. 21, 2005 (TW) 94124767

(51) Int. Cl. C23C 14/00

(52) U.S. Cl. 204/298.01

(57) ABSTRACT

An automatic in-line sputtering system with an integrated surface corona pretreatment includes a first loading region, a corona processing region, a first unloading/reversible region, a first return region, a transfer region, a second loading region, a pressure-down region, a sputtering region, a pressure-up region, a second unloading/reversible region, and a second return region. The substrate is transported by different carriers in the corona processing region and the sputtering region for the conductive issues, respectively. The carriers are recycled in two corresponding independent internal return regions that make the carriers without having to expose in an open environment. As a result, no fingerprint/dust adheres on the surface of carriers and the pollution of the transport process can be minimized. The system is integrated in a real close and in-line type to achieve the functions of continuous process, automation, cleanness and efficiency.

### BACKGROUND OF THE INVENTION

1. Field of the Invention

The present invention relates generally the conventional surface corona treatment and in-line sputtering equipment in an integrated system, and more particularly to an automatic in-line sputtering system with an integrated surface corona pretreatment.

2. Description of the Related Art

Generally, plastics have chemically inert and nonporous surfaces with low surface tensions and poor energy distribution that cause them to be nonreceptive to bonding with printing inks, coatings and adhesives. The ultimate goal of the surface treatment system is to increase the surface energy of material being treated. An increase in surface energy will promote the wettability and adhesion characteristics of the surface of the material. This is a critical accomplishment in most plastic converting, printing and sputtering processes. This application is referred to as pre-treatment. Corona is one of the most popular processes to enhance the surface energy of the plastic materials. Recent years have brought a distinct trend toward in-line corona treatment or pre-treatment on coating, laminating, printing or sputtering system. One of the factors contributing the trend is that treatment levels decay somewhat with time and can be seriously weakened by contact with the roller or operator during the subsequent machine operations. However, for the plastic substrates in the conventional sputtering process, the substrates are usually pre-treated by the first static electricity/dust removal and elimination for cleanness, and then by an external corona treatment for enhancing the surface energy. The substrates are placed on a carrier for translation and delivered into the corona treatment. The treated substrates with enough surface energy are then dealt with the sputtering process for depositing PVD surface coatings. FIG. 1 is a flow chart of the conventional corona/sputtering processes and there are some drawbacks in the processes.

Firstly, after the corona pre-treatment in an external apparatus, the substrates and carrier are taken out of the apparatus, and waited for the sputtering process. During the waiting period, the substrates and carrier expose in an open atmosphere environment that the dust will pollute the substrates and carrier. Therefore, the carrier and substrates are dealt with the second static electricity/dust removal and elimination prior to the sputtering process, if necessary, as shown in FIG. 1. The longer the waiting period, the more the amount of the pollution with the decay of the surface energy. Besides, at least one additional operator is required for the connection and transport between the corona pre-treatment and the sputtering process. It results that not only the fingerprints of the operator pollute the surfaces of the carrier, but also the contacts will weaken the corona effect. These drawbacks make the corona pre-treatment fail to produce the expected effect so that the undesired optical character, unusual convexity or exceptional penetrability of the surface is caused.

Secondary, because the corona is an electrical discharge process brought on by the ionization of a neutral fluid, usually air, surrounding a conductor, which occurs when the potential gradient exceeds a certain value, the carrier is basically nonconductive for the corona treatment to prevent the unnecessary or unexpected induced discharges. On the contrary, the carrier will become conductive after metal target sputtering process because the deposited metal particles will be distributed and adhered on the surface of the carrier. In other words, the conductive issue of the carrier for the corona process is opposite to that for the sputtering process. For the different requirements of the carriers, the substrates have to be taken out of the nonconductive carrier after the corona pre-treatment, and be replaced on another conductive carrier for the sputtering process. Therefore, the substrates are dealt with two independent processes and it results that the conventional corona/sputtering processes are not in a real close and in-line type.

Thirdly, the layout of the conventional recycle apparatus of the in-line sputtering system is usually external and horizontal “π” type to achieve the closed loop system. As a result, not only triple or more additional space will be occupied for the factory, but also the dust will adhere on the surface of the carrier because the recycle apparatus are usually placed in an open atmosphere environment, not in an isolated or vacuum condition.

### SUMMARY OF THE INVENTION

The primary objective of the present invention is to provide an automatic in-line sputtering system with an integrated surface corona pretreatment, where the decay of the corona pre-treatment with time can be minimized and therefore the corona effect of the substrates can be maintained.

The secondary objective of the present invention is to provide an automatic in-line sputtering system with an integrated surface corona pretreatment, where neither exposure in an open atmosphere environment is happened, nor any additional operator for the connection between the corona pre-treatment and the sputtering process is required.

The third objective of the present invention is to provide an automatic in-line sputtering system with an integrated surface corona pretreatment, where no dust and fingerprints are involved in the transport and recycle processes.

The fourth objective of the present invention is to provide an automatic in-line sputtering system with an integrated surface corona pretreatment, where two independent internal return regions are designed to solve the conductive issues of the carriers, and reduce the occupied horizontal space of the system.

The fifth objective of the present invention is to provide an automatic in-line sputtering system with an integrated surface corona pretreatment, where the corona pre-treatment and the sputtering process are integrated in a close and in-line type.

According to the objectives of the present invention, an automatic in-line sputtering system with an integrated surface corona pretreatment includes a first loading region, in which a first elevating and transporting device is provided for reciprocation between a first position and a second position in a vertical direction and transportation in a horizontal direction; a corona processing region beside the first loading region, in which a first transporting device and a discharge electrode above the first transporting device for corona pre-treatment are provided; a first unloading/reversible region beside the corona processing region, in which a second elevating and transporting device is provide for reciprocation between a first position and a second position in a vertical direction and transportation in a horizontal direction; a first return region, which is a channel connecting the first loading region and the first unloading/reversible region, and a first return device is provided for transportation; a transfer region beside the first unloading/reversible region having a holder device; a second loading region beside the transfer region, in which a third elevating and transporting device is provide for reciprocation between a first position and a second position in a vertical direction and transportation in a horizontal direction; a pressure-down region connected to the second loading region, in which a second transporting device is provided; a sputtering region connected to the pressure-down region, in which a third transporting device is provided; a pressure-up region connected to the sputtering region, in which a fourth transporting device is provided; a second unloading/reversible region connected to the pressure-up region, in which a fourth elevating and transporting device is provide for reciprocation between a first position and a second position in a vertical direction and transportation in a horizontal direction; and a second return region, which is a channel connecting the second unloading/reversible region and the second loading region, and a second return device is provided for transportation.

### BRIEF DESCRIPTION OF THE DRAWINGS

FIG. 1 is a flow chart of the conventional corona and sputtering processes;

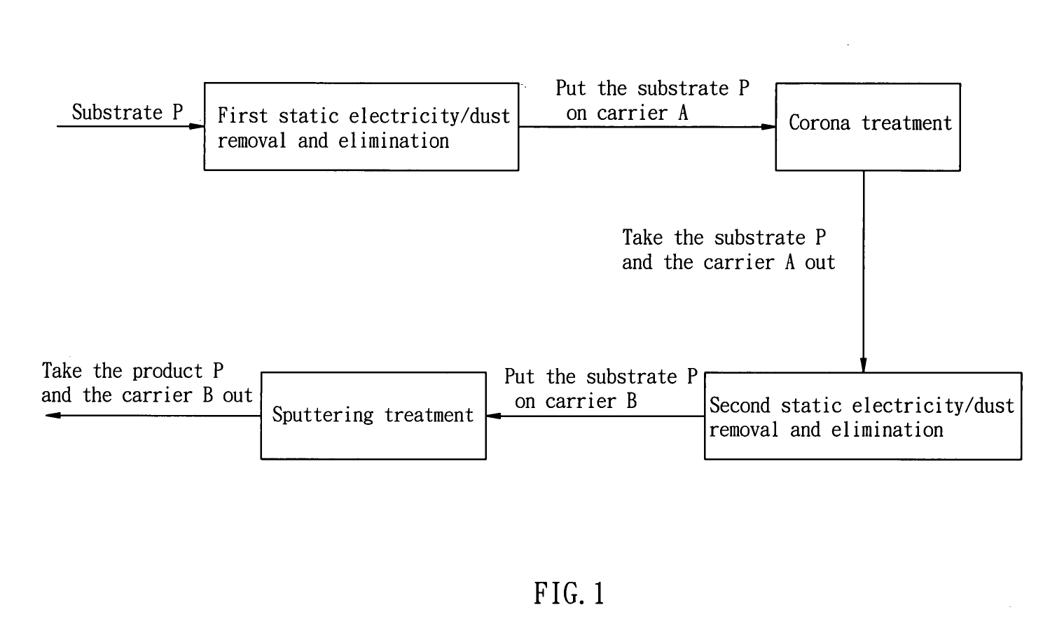

FIG. 2 is a sketch diagram of a preferred embodiment of the present invention, showing the elevating and transporting devices at the first position to transport the carriers in forward motion;

FIG. 3 is sketch diagram of the preferred embodiment of the present invention, showing the elevating and transporting devices at the second position to transport the carriers in backward motion; and

FIG. 4 is a flow chart of the preferred embodiment of the present invention.

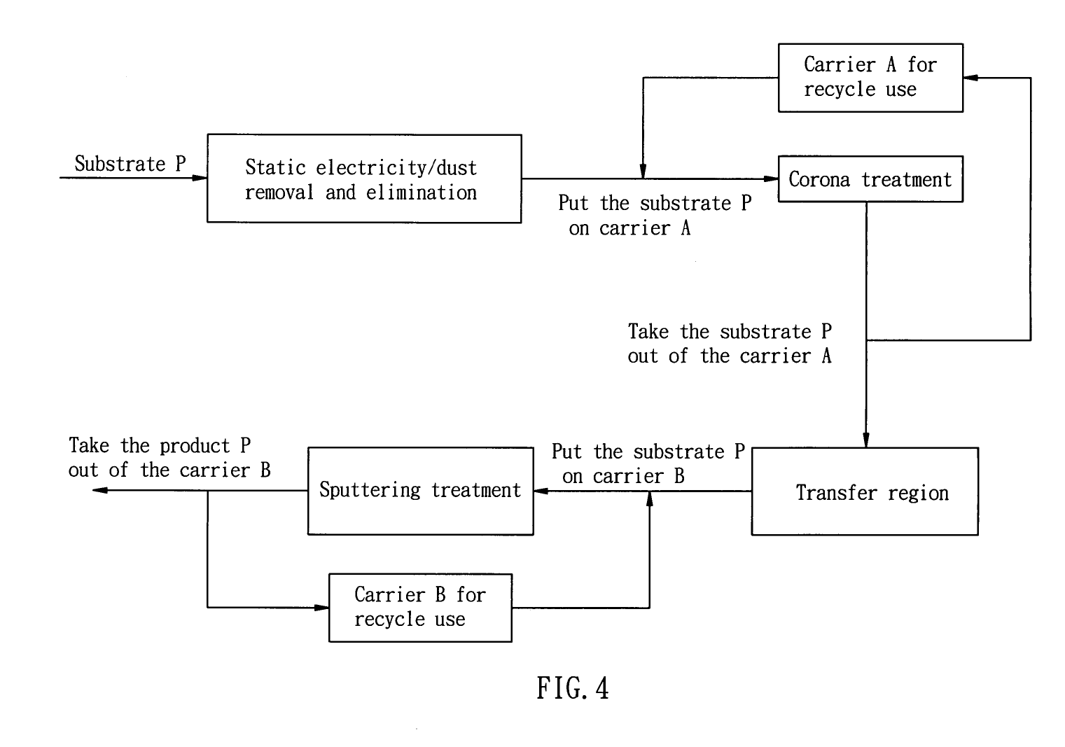

### DETAILED DESCRIPTION OF THE INVENTION

An automatic in-line sputtering system with an integrated surface corona pretreatment of the preferred embodiment of the present invention comprises:

A first loading region 10 is provided with a first elevating and transporting device 11 therein for reciprocation between a first position and a second position in a vertical direction. The first elevating and transporting device 11 also can transport the carrier A in a horizontal direction.

A corona processing region 20 is provided next to the first loading region 10, in which a first transporting device 21 and a discharge electrode 22 above the first transporting device 21 for corona pre-treatment are provided therein.

A first unloading/reversible region 30 is provided next to the corona processing region 20, in which a second elevating and transporting device 31 is provided for reciprocation between a first position and a second position in a vertical direction. The second elevating transporting device 31 also can transport the carrier A in a horizontal direction.

A first return region 40, which is a channel connecting the first loading region 10 and the first unloading/reversible region 30, and a first return device 41 is provided for transportation.

A transfer region 50 is provided at a side of the first unloading/reversible region 30 having a holder device. The holder device may be a robot arm or a sucker.

A second loading region 60 is provided next to the transfer region 50, in which a third elevating and transporting device 61 is provided for reciprocation between a first position and a second position in a vertical direction. The third elevating and transporting device 61 also can transport the carrier B in a horizontal direction.

A pressure-down region 70 with two gates on opposite ends thereof, is used to achieve an expected vacuum condition gradually, prior to the sputtering process. One of the gates is connected to the second loading region 60. The pressure-down region 70 is provided with a second transporting device 71 and may have one or more chambers therein to achieve the expected vacuum condition.

A sputtering region 80 is connected to the pressure-down region 70, which has two gates at opposite sides and a third transporting device 81 therein.

A pressure-up region 90 with two gates on opposite ends thereof, is used to recover the atmosphere condition gradually. One of the gates is connected to the sputtering region 80. The pressure-up region 90 is provided with a fourth transporting device 91 and may have one or more chambers therein to achieve the expected atmosphere condition.

A second unloading/reversible region 100 is connected to the pressure-up region 90, in which a fourth elevating and transporting device 101 is provided for reciprocation between a first position and a second position in a vertical direction. The fourth elevating and transporting device 101 also can transport the carrier B in a horizontal direction.

A second return region 110, which is a channel connecting the second unloading/reversible region 100 and the second loading region 60, in which a second return device 111 is provided for transportation.

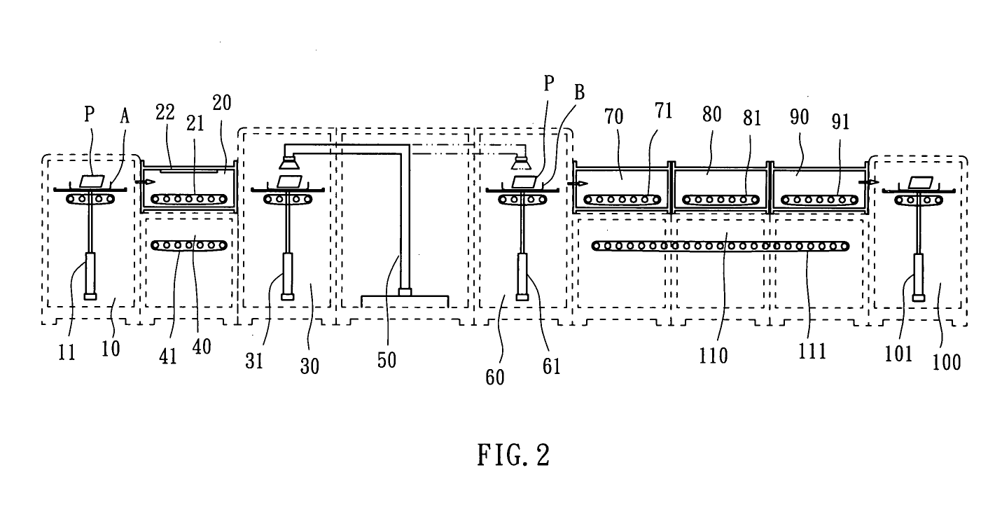

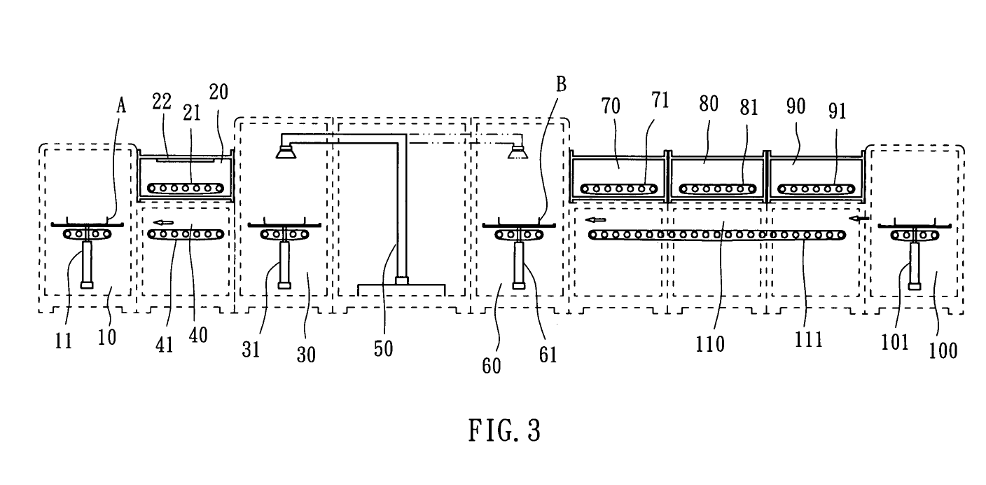

It may provide an additional cleaning region (not shown in the FIGS. 2 and 3) in front of the first loading region 10 for static electricity/dust removal and elimination. A substrate P, which had been treated in the cleaning region, is placed on a carrier A and delivered into the first loading region 10, as shown in FIG. 2. The first transporting device 21 will transport the carrier A, with the substrate P thereon, to the discharge electrode 22 in the corona processing region 20 for corona pre-treatment. After that, the carrier A is transported to the first unloading/reversible region 30, and the transfer region 50 will take the substrate P out and put it on another carrier B. Then, the carrier B is transported in forward motion by the third elevating and transporting device 61 of the second loading region 60. When the substrate P is taken out of the carrier A, the second elevating and transporting device 31 lowers the carrier A from the first position to the second position, as shown in FIG. 3, and the carrier A is transported backward to the first elevating and transporting device 11 through the first return device 41 of the first return region 40. Then, the first elevating and transporting device 11 elevates the carrier A back to the first position for the next substrate P. Because the first return region 40 is located under the corona processing region 20, it is an internal recycle apparatus and no additional space is occupied. Unlike the conventional processes, no additional operator is required, hence no the fingerprints/dust can adhere on the surface of carrier A with the effective isolation, so that the pollution of the transport process can be minimized.

The carrier B is transported from the second loading region 60 to the pressure-down region 70 by the third elevating and transporting device 61. Then, it is transported from the pressure-down region 70 to the sputtering region 80 by the second transporting device 71. The substrate P is coated and accomplished in the sputtering region 80. After the sputtering process, the carrier B is transported from the pressure-up region 90 to the second unloading/reversible region 100 by the fourth transporting device 91. The operator takes the product P out of the second unloading/reversible region 100, and the fourth elevating and transporting device 101 lowers the carrier B from the first position to the second position, as shown in FIG. 3. The carrier B is transported backward to the third elevating and transporting device 61 through the second return device 111 of the second return region 110. Then, the third elevating and transporting device 61 elevates the carrier B back to the first position for the next substrate P from the transfer region 50. Because the second return region 110 is located under the sputtering region 80, it is another internal recycle apparatus and no additional space is occupied. Unlike the conventional processes, no additional operator is required, hence no the fingerprints/dust can adhere on the surface of carrier A with the effective isolation, so that the pollution of the transport process can be minimized.

As a result, the processes of the present invention are integrated in a close and in-line type with no contact or pollution sources, such as operator and dust, to prevent the pollution problem of the conventional processes described in the background. In addition, the carrier A and the carrier B are recycled in two corresponding independent internal return regions that makes the carriers without having to expose in an open environment and keeps them clean. It improves the quality of the products and the efficiency of the system, effectively.

The pattern of the present invention is not restricted to the only straight line type, but can be rearranged in any type for the real space requirement. The important issue of the present invention is that the present invention is integrated in a real close and in-line type to achieve the functions of continuous process, automation, cleanness and efficiency.

The description above is a few preferred embodiments of the present invention and the equivalence of the present invention is still in the scope of the claim of the present invention.

What is claimed is:

1. An automatic in-line sputtering system with an integrated surface corona pretreatment, comprising:
a first loading region, in which a first elevating and transporting device is provide for reciprocation between a first position and a second position in a vertical direction and transportation in a horizontal direction;
a corona processing region next to the first loading region, in which a first transporting device and a discharge electrode above the first transporting device for a corona treatment are provided;
a first unloading/reversible region next to the corona processing region, in which a second elevating and transporting device is provide for reciprocation between a first position and a second position in a vertical direction and transportation in a horizontal direction;
a first return region having a channel connecting the first loading region and the first unloading/reversible region, in which a first return device is provided for transportation;
a transfer region beside the first unloading/reversible region having a holder device;
a second loading region beside the transfer region, in which a third elevating and transporting device is provide for reciprocation between a first position and a second position in a vertical direction and transportation in a horizontal direction;
a pressure-down region connected to the second loading region, in which a second transporting device is provided;
a sputtering region connected to the pressure-down region, in which a third transporting device is provided;
a pressure-up region connected to the sputtering region, in which a fourth transporting device is provided;
a second unloading/reversible region next to the pressure-up region, in which a fourth elevating and transporting device is provide for reciprocation between a first position and a second position in a vertical direction and transportation in a horizontal direction; and
a second return region having a channel connecting to the second unloading/reversible region and the second loading region, in which a second return device is provided for transportation.

2. The system as defined in claim 1, wherein the holder device is a robot arm.

3. The system as defined in claim 1, wherein the holder device is a sucker.

4. The system as defined in claim 1, further comprising an additional cleaning region in front of the first loading region for static electricity/dust removal and elimination.
